(19) United States
(12) Patent Application Publication
(10) Pub. No.: US 2002/0018960 A1
(43) Pub. Date: Feb. 14, 2002

(54) Novel photoresist polymers, and photoresist compositions containing the same

(76) Inventors: Geun Su Lee, Kyoungki-do (KR); Jae Chang Jung, Kyoungki-do (KR); Hyeong Soo Kim, Kyoungki-do (KR); Ki Ho Baik, Kyoungki-do (KR); Min Ho Jung, Kyoungki-do (KR)

Correspondence Address: MARSHALL, O'TOOLE, GERSTEIN, MURRAY & BORUN, 6300 SEARS TOWER, 233 SOUTH WACKER DRIVE, CHICAGO, IL, 60606-6402, US

(21) Appl. No.: 09/862,199

(22) Filed: May 21, 2001

(30) Foreign Application Priority Data
Jun. 21, 2000 (KR) 2000-34101

(51) Int. Cl. G03F 7/038; G03F 7/20; G03F 7/38; G03F 7/40

(52) U.S. Cl. 430/270.1; 430/296; 430/311; 430/330; 430/325

(57) ABSTRACT

Photoresist polymers represented by following Formula 3, and photoresist compositions using the same. The photoresist composition has high etching resistance, heat resistance and adhesiveness, and can be developed in aqueous tetramethylammonium hydroxide (TMAH) solution. The photoresist composition has low absorbance of a light source having wavelength of 193 nm and 157 nm, and thus is suitable for a photolithography process employing ultraviolet light sources such as ArF (193 nm) and VUV (157 nm) in fabricating minute circuits for high integration semiconductor devices.

Formula 3

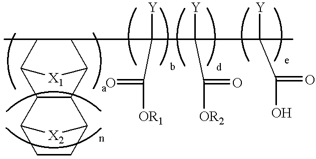

### BACKGROUND OF THE INVENTION

1. Field of the Invention

The present invention relates to photoresist polymers and photoresist compositions comprising the same. In particular, the present invention relates to photoresist polymers and compositions suitable for a photolithography processes employing deep ultraviolet light sources such as ArF (193 nm) and vacuum ultraviolet VUV (157 nm).

2. Description of the Background Art

A photoresist (PR) polymer for an ArF or VUV photolithography process should have a variety of physical characteristics, such as low absorbency of 193 nm and 157 nm wavelengths, and excellent etching resistance and adhesiveness. In addition, the photoresist should be easily developable in a commercially available developing solution, such as aqueous tetramethylammonium hydroxide (TMAH) solutions having concentrations of 2.38 or 2.6 wt % or thereabouts.

There has been much research done on resins having a high transparency at a wavelength of 193 nm and dry etching resistance similar to Nobolac resin. However, most of the photoresists are not suitable for VUV due to their poor transmittance at 157 nm wavelength. Photoresists containing fluorine and silicon have good transmittance at these wavelengths. Unfortunately, most photoresists containing fluorine with a polyethylene or polyacrylate polymer backbone have weak etching resistance, low solubility in commercially available aqueous TMAH solutions and poor adhesiveness to the silicon wafer. In addition, these photoresists are difficult to mass-produce and are expensive. Furthermore, during a post-exposure bake (PEB) process these photoresist can generate HF which can contaminate a lens or corrode a device. Thus, these photoresists are generally not suitable for commercial use. On the other hand, photoresists containing silicon require a two-step process such as HF treatment and O₂ treatment during the etching process. And because it is difficult to remove the HF completely, these types of photoresists are generally not suitable in the production of semiconductor devices.

In an attempt to overcome some of the above-described disadvantages, the present inventors have found that a polymer having low absorbance of a light source having wavelengths of 193 nm and 157 nm can be prepared by synthesizing a polymer of alicyclic monomer and maleic anhydride derivative, and by introducing a variety of protecting groups by opening the ring of the maleic anhydride section of the polymer.

### SUMMARY OF THE DISCLOSURE

Accordingly, novel photoresist polymers that can be used in a light source such as ArF (193 nm) and VWV (157 nm), and photoresist compositions containing the same are disclosed.

### BRIEF DESCRIPTION OF THE DRAWINGS

FIG. 1 is a photograph showing a pattern obtained in Example 7.

FIG. 2 is a photograph showing a pattern obtained in Example 8.

FIG. 3 is a photograph showing a pattern obtained in Example 9.

FIG. 4 is a photograph showing a pattern obtained in Example 10.

### DETAILED DESCRIPTION OF THE PREFERRED EMBODIMENTS

The present invention provides novel photoresist polymers, which achieve the above-stated objective, and a process for preparing the same. The present invention also provides photoresist compositions comprising such a PR polymer and a semiconductor device fabricated by using such a PR compositions.

In one particular aspect, the present invention provides a photoresist polymer of following Formula 3:

Formula 3

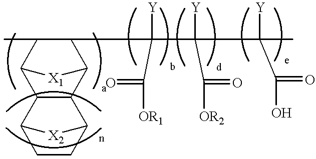

wherein, X₁ and X₂ are the same or different and are selected from the group consisting of CH₂, CH₂CH₂, O and S; Y is H, halogen or —OR₃; R₁ is a substituted linear or branched (C₁-C₁₀) alkyl; R₂ is —CH(CH₃)OR₄; R₃ is a substituted or unsubstituted linear or branched (C₁-C₁₀) alkyl; R₄ is a substituted or unsubstituted linear or branched (C₁-C₂₀) alkyl or aryl, a 5-7 membered ring cyclic group; n is an integer of 0 or 1; and the ratio of a:b:d:e is within the range defined by 50 mol %: 5-45 mol %:0-30 mol %:0-20 mol %.

Preferably, the polymer of formula 3 is selected from the group consisting of compounds of following Formulas 3a to 3d:

Formula 3a

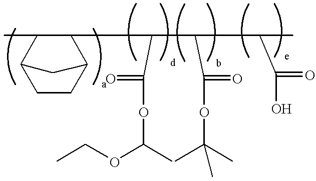

Formula 3b

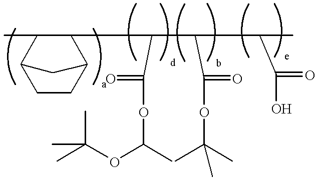

Formula 3c

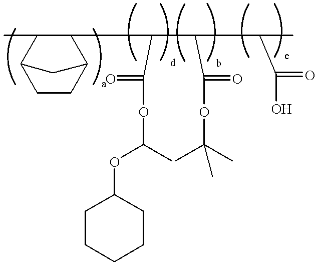

Formula 3d

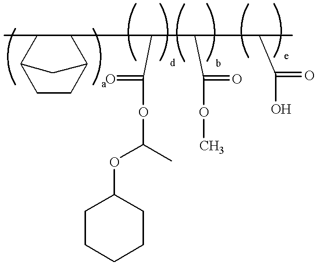

wherein the ratio of a:b:d:e is within the range 50 mol %:5-45 mol %:0-30 mol %:0-20 mol %.

The compound of Formula 3 can be prepared by a process comprising the steps of:

(a) polymerizing compounds of the following Formula 4 with the alicyclic compound of the following Formula 5 to obtain a polymer of following Formula 1;

(b) preparing a polymer of following Formula 2 containing an ester group and a hydroxyl group, by reacting the polymer of Formula 1 with alcohol or alkoxide compound to open the ring of the moiety of Formula 4 in the polymer; and

(c) partially or wholly esterizing or acetalizing the carboxyl groups in the polymer of Formula 2 to obtain a polymer of Formula 3.

Formula 1

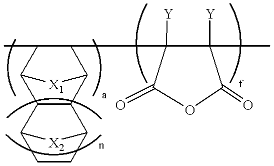

Formula 2

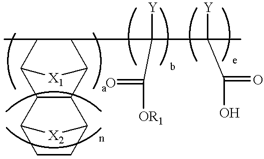

Formula 3

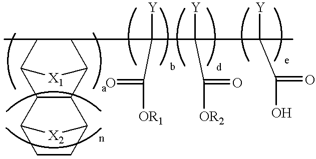

Formula 4

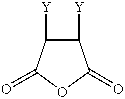

Formula 5

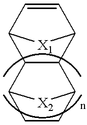

wherein, X₁, X₂, Y, R₁, R₂, R₃; R₄ and n are those defined above; a is about 50 mol %, b ranges from about 5 to about 45 mol %, c ranges from about 5 to about 40 mol %, d ranges from about 0 to about 30 mol %, e ranges from about 0 to about 20 mol % and f is about 50 mol %.

In step (a), exemplary solvents suitable for polymerization include tetrahydrofuran, dimethylformamide, dimethylsulfoxide, dioxane, benzene, toluene, xylene, propyleneglycol methyl ether acetate and ethyl lactate. In addition, a solvent for crystallizing and purifying the polymer is preferably selected from the group consisting of diethyl ether, petroleum ether, lower alcohol such as methanol, ethanol and isopropanol, water, and mixtures thereof.

In step (c), the compound of Formula 2 reacts with a compound having a protecting group in order to partially protect the carboxylic group. Here, the compound having the protecting group is a vinylether compound comprising (C₁-C₂₀) alkyl, cycloalkyl or aryl group.

Another aspect of the present invention provides a polymer of the above Formula 2 which is used as an intermediate for preparing the photoresist polymer of Formula 3.

The compound of Formula 2 is selected from the group consisting of compounds of following Formulas 2a and 2b:

Formula 2a

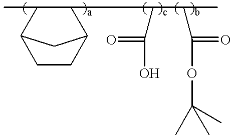

Formula 2b

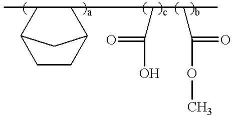

wherein, a is about 50 mol %, b ranges from about 5 to about 45 mol %, and c ranges from about 5 to about 40 mol %.

In addition, the present invention provides a photoresist composition comprising (i) the photoresist polymer of Formula 3; (ii) a photoacid generator; and (iii) an organic solvent.

Preferred photoacid generators have a relatively low light absorbency in the wavelengths of 157 nm and 193 nm. More preferably, the photoacid generator is selected from the group consisting of phthalimidotrifluoromethane sulfonate, dinitrobenzyltosylate, n-decyl disulfone and naphthylimido trifluoromethane sulfonate.

The photoacid generator can further comprise a compound selected from the group consisting of diphenyl iodide hexafluorophosphate, diphenyl iodide hexafluoroarsenate, diphenyl iodide hexafluoroantimonate, diphenyl p-methoxyphenyl triflate, diphenyl p-toluenyl triflate, diphenyl p-isobutylphenyl triflate, triphenylsulfonium hexafluoroarsenate, triphenylsulfonium hexafluoroantimonate, triphenylsulfonium triflate and dibutylnaphthylsulfonium triflate.

The photoacid generator is used in an amount of 0.1 to 10 wt % of the photoresist resin employed.

Exemplary organic solvents suitable in PR compositions of the present invention include ethyl 3-ethoxypriopionate, methyl 3-methoxypropionate, cyclohexanone, propyleneglycol methyl ether acetate, n-heptanone and ethyl lactate.

The amount of solvent used is preferably in the range of from about 400% to about 1500% by weight of the PR polymer. This ratio has been found to be particularly useful in obtaining a photoresist layer of a desirable thickness when coated on to a suitable substrate such as a silicon wafer in production of a semiconductor element. In particular, it has been found by the present inventors that when the amount of organic solvent is about 1000% by weight of the photoresist polymer, a photoresist composition layer having 0.2 μm of thickness can be obtained.

Yet another aspect of the present invention provides a process for forming a photoresist pattern, comprising the steps of:

(a) coating a photoresist composition described above on a substrate to form a photoresist film;

(b) exposing said photoresist film to light using a light source; and

(c) developing said photoresist film.

The process for forming the photoresist pattern can further include a baking step before and/or after the exposure step (b). Preferably, the baking step is performed at temperature in the range of from about 70 to about 200° C.

Exemplary light sources which are useful for forming the photoresist pattern include ArF, KrF, EUV, VUV, E-beam, X-ray or ion beam. Preferably, the irradiation energy is in the range of from about 1 mJ/cm² to about 30 mJ/cm².

Furthermore, the present invention provides a semiconductor device, which is manufactured according to the process for forming the photoresist pattern described above.

Additional objects, advantages, and novel features of this invention will become apparent to those skilled in the art upon examination of the following examples, which are not intended to be limiting.

I. Preparation of Photoresist Polymers

### EXAMPLE 1

### Synthesis of Polymer of Formula 2a

(Step 1) Synthesis of Poly(norbornylene/maleic Anhydride

To 50 ml of tetrahydrofuran was added 0.2 mole of norbornylene, 0.2 mole of maleic anhydride and 0.4 g of 2,2′azobisisobutyronitrile (AIBN). The resulting mixture was stirred at 67° C. for 8 hours. Thereafter, the polymer was precipitated and filtered in petroleum ether/ether(1/1) solution, to obtain poly(norbornylene/maleic anhydride) (Formula 1) (yield: 58%).

(Step 2) Synthesis of Polymer of Formula 2a

To 100 ml of tetrahydrofuran was added 18.2 g of poly(norbornylene/maleic anhydride) synthesized in step 1, and 7.4 g of potassium tert-butoxide, and the resulting solution was reacted at a room temperature (23° C.) for 24 hours. Thereafter, the resulting solution was cooled, and 100 ml of water was added thereto. The resin was precipitated, filtered and dried to obtain the polymer of Formula 2a. Here, the precipitate was washed with water (yield: 83%).

### EXAMPLE 2

### Synthesis of Polymer of Formula 2b

To 100 ml of tetrahydrofuran was added 18.2 g of poly(norbornylene/maleic anhydride) synthesized in Example 1 (step 1), 3.2g of methanol and 0.1 ml of sulfuric acid, and the resulting solution was reacted at 40° C. for 24 hours. Thereafter, the resulting solution was cooled, and 100 ml of water was added thereto. The resin was precipitated, filtered and dried to obtain the polymer of Formula 2b (yield: 87%).

### EXAMPLE 3

### Synthesis of Polymer of Formula 3a

To 100 ml of tetrahydrofuran was added the polymer of Formula 2a prepared in Example 1 (18g), p-toluensufonic acid (10 mg) and ethylvinylether (7.2g), and the resulting solution was reacted at a low temperature (10° C.) for 20 hours. Thereafter, the resulting solution was distilled to partially remove tetrahydrofuran, precipitated in petroleum ether, and filtered. The resulting polymer was vacuum dried to obtain the polymer of Formula 3a (yield: 76%).

### EXAMPLE 4

### Synthesis of Polymer of Formula 3b

To 100 ml of tetrahydrofuran was added the polymer of Formula 2a prepared in Example 1 (18 g), p-toluensufonic acid (10 mg) and tert-butylvinylether (10.0 g), and the resulting solution was reacted at a low temperature (10° C.) for 8 hours. Thereafter, the resulting solution was distilled to partially remove tetrahydrofuran, precipitated in petroleum ether, and filtered. The resulting polymer was vacuum dried to obtain the polymer of Formula 3b (yield: 75%).

### EXAMPLE 5

### Synthesis of Polymer of Formula 3c

To 100 ml of tetrahydrofuran was added the polymer of Formula 2a prepared in Example 1 (18 g), p-toluensufonic acid (10 mg) and cyclohexylvinylether (12.6g), and the resulting solution was reacted at a low temperature (10° C.) for 8 hours. Thereafter, the resulting solution was distilled to partially remove tetrahydrofuran, precipitated in petroleum ether, and filtered. The resulting polymer was vacuum dried to obtain the polymer of Formula 3c (yield: 82%).

### EXAMPLE 6

### Synthesis of Polymer of Formula 3d

To 100 ml of tetrahydrofuran was added the polymer of Formula 2b prepared in Example 2 (18 g), p-toluensufonic acid (10 mg) and cyclohexylvinylether (10.0 g), and the resulting solution was reacted at a low temperature (10° C.) for 8 hours. Thereafter, the resulting solution was distilled to partially remove tetrahydrofuran, precipitated in petroleum ether, and filtered. The resulting polymer was vacuum dried to obtain the polymer of formula 3d (yield: 82%).

II. Preparation of Photoresist Compositions and Formation of Patterns

### EXAMPLE 7

To 100 g of propyleneglycol methyl ether acetate was added the polymer prepared in Example 3 (10 g), phthalimidotrifluoromethane sulfonate (0.06 g) and triphenylsulfonium triflate (0.06g). The resulting mixture was stirred and filtered through 20μm filter to obtain a photoresist composition.

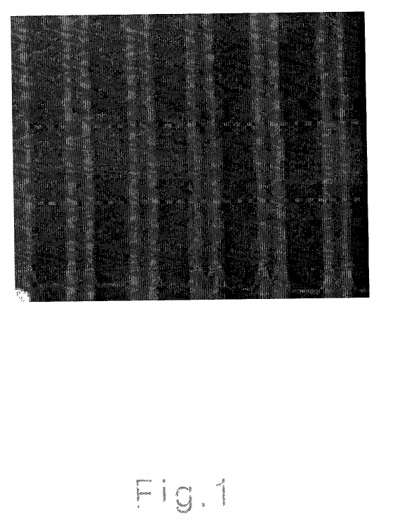

The photoresist composition was coated on a silicon wafer to form a photoresist thin film. The thin film was soft-baked in an oven or hot plate of 130° C. for 90 seconds, exposed to light using an ArF exposer, post-baked at 130° C. for 90 seconds, and developed in the 2.38wt % aqueous TMAH solution to obtain 110 nm L/S pattern (see FIG. 1).

### EXAMPLE 8

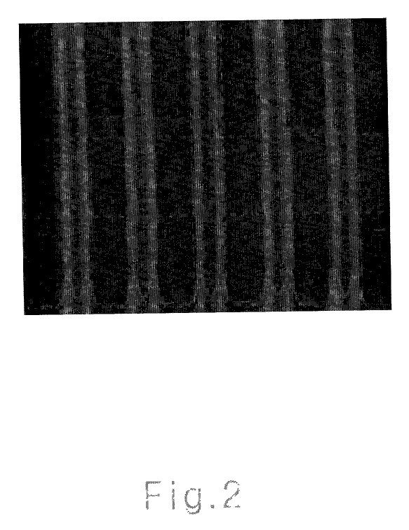

The procedure of Example 7 was repeated using the polymer of Example 4 instead of the polymer of Example 3 to obtain a 110 nm L/S pattern (see FIG. 2).

### EXAMPLE 9

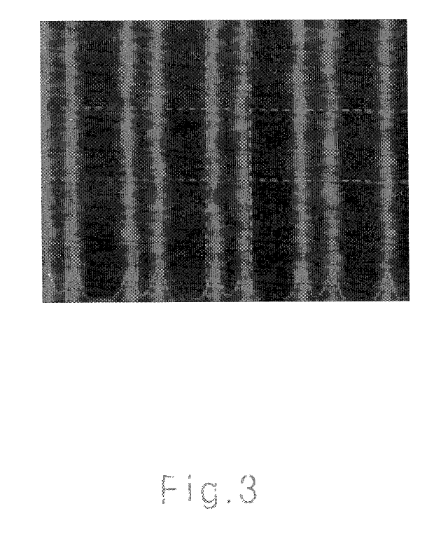

The procedure of Example 7 was repeated using the polymer of Example 5 instead of the polymer of Example 3 to obtain a 130 nm L/S pattern (see FIG. 3).

### EXAMPLE 10

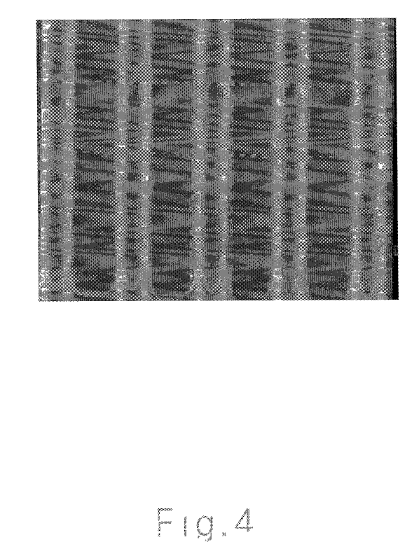

The procedure of Example 7 was repeated using the polymer of Example 6 instead of the polymer of Example 3 to obtain a 130 nm L/S pattern (see FIG. 4).

As discussed earlier, in accordance with the present invention, ring moiety of the alicyclic monomer-maleic anhydride polymer is opened, and at least one protecting group is introduced thereto. As a result, the photoresist polymer of the present invention has an improved contrast ratio, can be easily developed in a conventional alkaline developing solution, and has low absorbance of a light source having wavelength of 193 nm and 157 nm. Therefore, photoresist compositions of the present invention can be advantageously used as 193 nm and 157 nm wavelength photoresist layer in a semiconductor device.

The foregoing discussion of the invention has been presented for purposes of illustration and description. The foregoing is not intended to limit the invention to the form or forms disclosed herein. Although the description of the invention has included description of one or more embodiments and certain variations and modifications, other variations and modifications are within the scope of the invention, e.g., as may be within the skill and knowledge of those in the art, after understanding the present disclosure. It is intended to obtain rights which include alternative embodiments to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. A photoresist polymer of following formula: 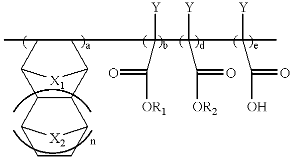
wherein, X₁ and X₂ are the same or different and are selected from the group consisting of CH₂, CH₂CH₂, O and S; Y is H, halogen or —OR₃; R₁ is a substituted or unsubstituted linear or branched (C₁-C₁₀) alkyl; R₂ is —CH(CH₃)OR₄; R₃ is a substituted or unsubstituted linear or branched (C₁-C₁₀) alkyl; R₄ is a substituted or unsubstituted linear or branched (C₁-C₂₀) alkyl or aryl, or a 5-7 membered ring cyclic group; n is an integer of 0 or 1; and the ratio of a:b:d:e is 50 mol %: from about 5 to about 45 mol %: from about 0 to about 30 mol %: from about 0 to about 20 mol %.

2. The photoresist polymer of claim 1 wherein the polymer is further defined as being selected from the group consisting of compounds of: 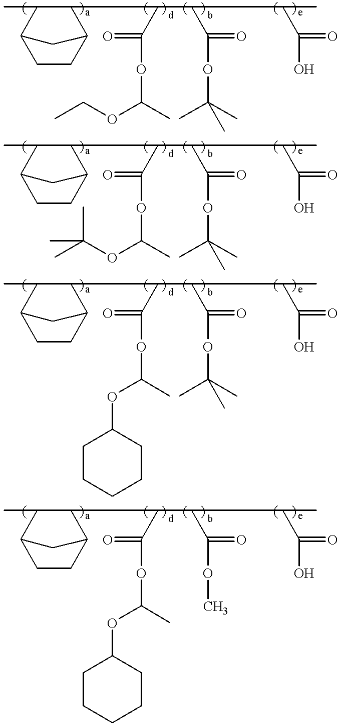
wherein the ratio of a:b:d:e is about 50 mol %: from about 5 to about 45 mol %: from about 0 to about 30 mol %: from about 0 to about 20 mol %.

3. A process for preparing a photoresist polymer comprising:
(a) polymerizing compounds of Formula 4 with the alicyclic compounds of Formula 5 to obtain a polymer of the following Formula 1;
(b) preparing a polymer of Formula 2 containing an ester group and a hydroxyl group, by reacting the polymer of Formula 1 with alcohol or alkoxide compound to open the ring of the moiety of Formula 4 in the polymer; and
(c) partially or wholly esterizing or acetalizing the carboxyl groups in the polymer of Formula 2 to obtain a polymer of Formula 3;
Formula 1 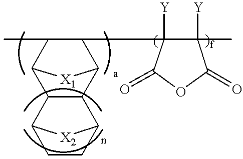
Formula 2 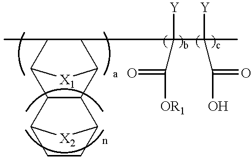
Formula 3 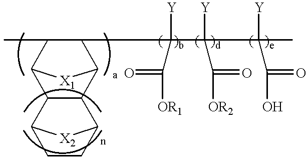
Formula 4 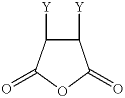
Formula 5 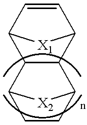
wherein, X₁ X₂ are the same or different and are selected from the group consisting of CH₂, CH₂CH₂, O and S; Y is H, halogen or —OR₃; R₁ is a substituted or unsubstituted linear or branched (C₁-C₁₀) alkyl; R₂ is —CH(CH₃)OR₄; R₃ is optionally substituted linear or branched (C₁-C₁₀) alkyl; R₄ is a substituted or unsubstituted linear or branched (C₁-C₂₀) alkyl or aryl, or a 5-7 membered ring cyclic group; n is an integer of 0 or 1; a is about 50 mol %, b from about 5 to about 45 mol %, c from about 5 to about 40 mol %, d from about 0 to about 30 mol %, e from about 0 to about 20 mol % and f is about 50 mol %.

4. The process of claim 3 wherein, in step (a), the polymerization solvent is selected from the group consisting of tetrahydrofuran, dimethylformamide, dimethylsulfoxide, dioxane, benzene, toluene, xylene, propyleneglycol methyl ether acetate and ethyl lactate.

5. The process of claim 3 wherein, in step (c), the compound of Formula 2 is partially protected by reacting the compound of Formula 2 with a compound comprising a protecting group.

6. The process of claim 5 wherein the compound comprising the protecting group is a vinylether compound comprising (C₁-C₂₀) alkyl, cycloalkyl or aryl group.

7. A polymer of following Formula 2 which can be esterized or acetalized to prepare the photoresist polymer of claim 1:
Formula 2 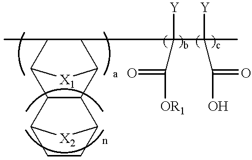
wherein, X₁ and X₂ are the same or different and are selected from the 17 group consisting of CH₂, CH₂CH₂, O and S; Y is H, halogen or —OR₃; R₁ is a substituted or unsubstituted linear or branched (C₁-C₁₀) alkyl; R₃ is a substituted or unsubstituted linear or branched (C₁-C₁₀) alkyl; n is an integer of 0 or 1; and the ratio of a:b:c is about 50 mol %: from about 5 to about 45 mol %: from about 5 to about 40 mol %.

8. The polymer of claim 7 which is selected from the group consisting of compounds of following Formulas 2a and 2b:
Formula 2a 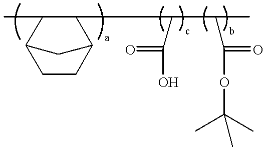
Formula 2b 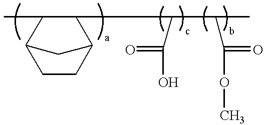
wherein, a is about 50 mol %, b from about 5 to about 45 mol %, and c from about 5 to about 40 mol %.

9. A photoresist composition comprising (i) a photoresist polymer of claim 1, (ii) a photoacid generator; and (iii) an organic solvent.

10. The photoresist composition of claim 9 wherein the photoacid generator is selected from the group consisting of phthalimidotrifluoromethane sulfonate, dinitrobenzyltosylate, n-decyl disulfone and naphthylimido trifluoromethane sulfonate.

11. The photoresist composition of claim 10 wherein the photoacid generator further comprises a compound selected from the group consisting of diphenyl iodide hexafluorophosphate, diphenyl iodide hexafluoroarsenate, diphenyl iodide hexafluoroantimonate, diphenyl p-methoxyphenyl triflate, diphenyl p-toluenyl triflate, diphenyl p-isobutylphenyl triflate, diphenyl p-tert-butylphenyl triflate, triphenylsulfonium hexafluororphosphate, triphenylsulfonium hexafluoroarsenate, triphenylsulfonium hexafluoroantimonate, triphenylsulfonium triflate, dibutylnaphthylsulfonium triflate and mixtures thereof.

12. The photoresist composition of claim 9 wherein the photoacid generator is present in an amount of 0.1 to 10% by weight of the photoresist polymer.

13. The photoresist composition of claim 9 wherein the organic solvent is selected from the group consisting of ethyl 3-ethoxypropionate, methyl 3-methoxypropionate, cyclohexanone, propyleneglycol methyl ether acetate, n-heptanone and ethyl lactate.

14. The photoresist composition of claim 9 wherein an amount of organic solvent ranges from about 400% to about 1500% by weight of the photoresist polymer.

15. A process for forming a photoresist pattern comprising:
(a) coating a photoresist composition of claim 9 on a substrate to form a photoresist film;
(b) exposing said photoresist film to light using a light source; and
(c) developing said photoresist film.

16. The process of claim 15 further comprising a baking step before and/or after the exposure step (b).

17. The process of claim 16 wherein the baking step or steps are performed at temperature ranging from about 70 to about 200° C.

18. The process of claim 15 wherein the light source is selected from the group consisting of ArF, KrF, EUV, VUV, E-beam, X-ray and ion beam.

19. The process of claim 15 wherein said photoresist film is irradiated with light-exposure energy ranging from about 1 to about 30 mJ/cm².

20. A semiconductor element manufactured by the process according to claim 15.
